(19) United States
(12) Patent Application Publication
(10) Pub. No.: US 2017/0097226 A1
(43) Pub. Date: Apr. 6, 2017

(54) THIN-FILM THICKNESS MEASURER AND THIN-FILM DEPOSITING APPARATUS INCLUDING THE SAME

(71) Applicant: SAMSUNG DISPLAY CO., LTD., YONGIN-SI (KR)

(72) Inventors: JIHOON SEO, YONGIN-SI (KR); PANMOK SON, YONGIN-SI (KR); DONGGYU YANG, YONGIN-SI (KR); JONGWOOK KIM, YONGIN-SI (KR); YONGJOON MOOK, YONGIN-SI (KR); JAEYOUNG PARK, YONGIN-SI (KR); KYOUNGHO YANG, YONGIN-SI (KR); JEONGGEUN YOO, YONGIN-SI (KR); JINTAE KIM, YONGIN-SI (KR)

(21) Appl. No.: 15/075,642

(22) Filed: Mar. 21, 2016

(30) Foreign Application Priority Data
Oct. 2, 2015 (KR) 10-2015-0139105

(51) Int. Cl. G01B 11/06; C23C 16/455; C23C 16/52

(52) U.S. Cl. CPC G01B 11/06; C23C 16/52; C23C 16/455

(57) ABSTRACT

Provided is a thin-film thickness measurement apparatus including a light output unit including a light emitter configured to emit light onto a target. A light receiving unit is configured to receive light reflected from the target. A blowing unit is configured to eject a gas around the light emitter.

### CROSS-REFERENCE TO RELATED APPLICATION

This application claims priority under 35 U.S.C. §119 to Korean Patent Application No. 10-2015-0139105, filed on Oct. 2, 2015, in the Korean Intellectual Property Office, the disclosure of which is incorporated by reference herein in its entirety.

1. Technical Field

One or more exemplary embodiments of the present invention relate to a thin-film thickness measurement apparatus, and more particularly to a thin-film deposition apparatus including the same.

2. Discussion of Related Art

During a thin-film manufacturing process for forming a thin-film of an organic light-emitting display apparatus, a deposition process may be used to attach the thin-film on a substrate surface by supplying a deposition source.

Uniformity of a light-emitting characteristic of the organic light-emitting display apparatus may be obtained by maintaining an accurate thickness. Thus, it may be desirable to have a thin-film thickness measurement apparatus for measuring the thickness of the thin-film that is maintained in a relatively uncontaminated state even after being used for a relatively long period of time.

### SUMMARY

One or more exemplary embodiments of the present invention may include a thin-film thickness measurement apparatus, which may reduce or eliminate a deterioration of measurement accuracy of the thin-film thickness measurement apparatus and a thin-film deposition apparatus including the thin-film thickness measurement apparatus. The deterioration of the measurement accuracy of the thin-film thickness measurement apparatus may result from contamination of the thin-film thickness measurement apparatus.

According to one or more exemplary embodiments of the present invention, a thin-film thickness measurement apparatus includes a light output unit including a light emitter configured to emit light onto a target. A light receiving unit is configured to receive light reflected from the target. A blowing unit is configured to eject a gas around the light emitter.

The light output unit may include a housing including a light source. An optical fiber may project from the housing to radiate light from the light source towards the target.

The blowing unit may include an ejecting block ejecting a gas towards a front end of the optical fiber facing the target. A sucking block may collect the gas ejected from the ejecting block.

The blowing unit may be configured to create air circulation including the gas from the ejecting block to the sucking block around the front end of the optical fiber.

The ejecting block and the sucking block may be coupled to the housing. An inflow line connected to the ejecting block and a discharge line connected to the sucking block may be disposed in the housing.

The ejecting block and the sucking block may include an acetal material.

The gas may include nitrogen.

According to one or more exemplary embodiments of the present invention, a thin-film deposition apparatus includes a deposition chamber configured to house a target. A deposition source supplier is configured to supply a source of a thin-film to be deposited on the target. A thin-film thickness measurement apparatus is configured to measure a thickness of the thin-film deposited on the target. The thin-film thickness measurement apparatus includes a light output unit including a light emitter configured to emit light onto the target. A light receiving unit is configured to receive light reflected from the target. A blowing unit is configured to eject a gas around the light emitter.

The light output unit may include a housing including a light source. An optical fiber may project from the housing to radiate light from the light source towards the target.

The blowing unit may include an ejecting block ejecting a gas towards a front end of the optical fiber facing the target. A sucking block may collect the gas ejected from the ejecting block.

The blowing unit may be configured to create air circulation including the gas from the ejecting block to the sucking block around the front end of the optical fiber.

The ejecting block and the sucking block may be coupled to the housing. An inflow line connected to the ejecting block and a discharge line connected to the sucking block may be disposed in the housing.

The ejecting block and the sucking block may include an acetal material.

The gas may include nitrogen.

### BRIEF DESCRIPTION OF THE DRAWINGS

The above and other features of the present invention will become more apparent by describing in detail exemplary embodiments thereof, with reference to the accompanying drawings, in which:

FIG. 1 is a diagram schematically illustrating a structure of a thin-film deposition apparatus including a thin-film thickness measurement apparatus, according to an exemplary embodiment of the present invention;

FIG. 2 is a front view of the thin-film thickness measurement apparatus of FIG. 1;

FIG. 3 is a diagram depicting an air circulation formed by a blowing unit of the thin-film thickness measurement apparatus of FIG. 2;

FIG. 4 is a graph showing a light quantity decreasing state of the thin-film thickness measurement apparatus of FIG. 2 according to time, together with a comparative example; and

FIG. 5 is a cross-sectional view of an organic light-emitting display apparatus as an example of a target for performing deposition by using the thin-film deposition apparatus of FIG. 1.

### DETAILED DESCRIPTION

Exemplary embodiments of the present invention will be described below in more detail with reference to the accompanying drawings. In this regard, the exemplary embodiments may have different forms and should not be construed as being limited to the exemplary embodiments of the present invention described herein.

In the specification and drawings, like reference numerals may refer to like elements.

Sizes of elements in the drawings may be exaggerated for clarity of description.

A specific process order according to exemplary embodiments of the present invention may be performed differently from the described order.

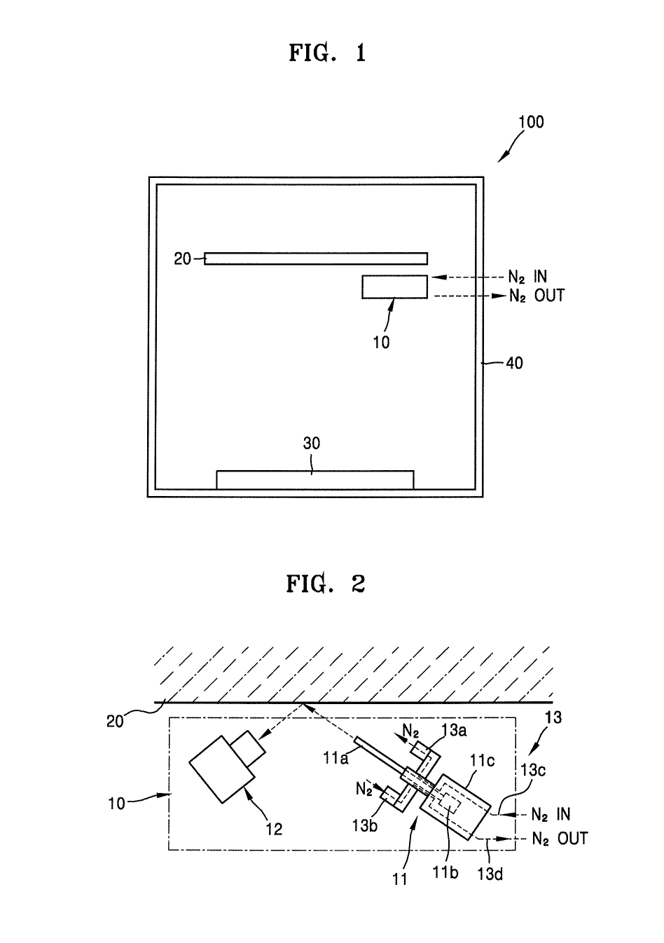

FIG. 1 is a diagram schematically illustrating a structure of a thin-film deposition apparatus including a thin-film thickness measurement apparatus, according to an exemplary embodiment of the present invention.

Referring to FIG. 1, a thin-film deposition apparatus 100 according to an exemplary embodiment of the present invention may include a deposition source supplier 30 supplying a source of a thin-film towards a substrate 20. The substrate 20 may be a deposition target inside a deposition chamber 40. A thin-film thickness measurement apparatus 10 may measure a thickness of the thin-film formed on the substrate 20 in the chamber 40.

Thus, when the deposition source supplier 30 supplies the source of the thin-film inside the deposition chamber 40, the thin-film may be deposited on the substrate 20 to form the thin-film having a certain thickness.

A mask having a pattern of the thin-film may be disposed between the deposition source supplier 30 and the substrate 20.

The thin-film thickness measurement apparatus 10 may be an apparatus measuring a thickness of a thin-film deposited on the substrate 20, and may have a structure shown in FIG. 2.

FIG. 2 is a front view of the thin-film thickness measurement apparatus 10 of FIG. 1. Referring to FIG. 2, the thin-film thickness measurement apparatus 10 may include a light output unit 11 radiating light for measuring a thickness of a thin-film on the substrate 20, and a light receiving unit 12 receiving light that is radiated from the light output unit 11 and reflected from the substrate 20. The thickness of the thin-film may be calculated as the light receiving unit 12 receives the light radiated from the light output unit 11 and reflected from the substrate 20. The light receiving unit 12 may measure a change of a polarization state of the light. For example, the thickness of the thin-film may be measured according to substantially the same principle as an ellipsometer.

The thin-film thickness measurement apparatus 10 may include a blowing unit 13 that directly ejects and circulates a clean nitrogen gas to a light emitter of the light output unit 11. The blowing unit 13 may increase measurement accuracy of the thin-film thickness measurement apparatus 10 and may increase productivity of a deposition process.

The light output unit 11 may include a housing 11c including a light source 11b, and an optical fiber 11a projecting from the housing 11c. The optical fiber 11a may transmit light from the light source 11b to the substrate 20. Thus, light radiated from the light source 11b may be emitted from a front end of the optical fiber 11a facing the substrate 20 and onto the substrate 20. If the front end of the optical fiber 11a is contaminated, light output quantity may be reduced, and thus measurement accuracy of the thin-film deposited on the substrate 20 may be reduced. The light output unit 11 may be disposed in the chamber 40 in which a deposition process is performed, and thus the front end of the optical fiber 11a may be contaminated by the source of the thin-film. When the front end of the optical fiber 11a is contaminated and the light output quantity is reduced, the thickness of the thin-film might not be accurately measured. Thus, the deposition process may be stopped periodically, and a process of cleaning the front end of the optical fiber 11a after opening the deposition chamber 40 may be performed, which may reduce productivity.

When the blowing unit 13 is used, the front end of the optical fiber 11a may be maintained in a relatively clean state even while the deposition process is performed. Thus, periodic stopping of the deposition process to clean the front end of the optical fiber 11a may be reduced or eliminated.

The blowing unit 13 may include an ejecting block 13a ejecting a clean external nitrogen gas to the front end of the optical fiber 11a, a sucking block 13b collecting the ejected nitrogen gas, an inflow line 13c transferring the clean external nitrogen gas outside the deposition chamber 40 to the ejecting block 13a, and a discharge line 13d discharging the nitrogen gas collected by the sucking block 13b. The ejecting block 13a and the sucking block 13b may be disposed on the housing 11c, and the inflow line 13c and the discharge line 13d may pass through inside the housing 11c.

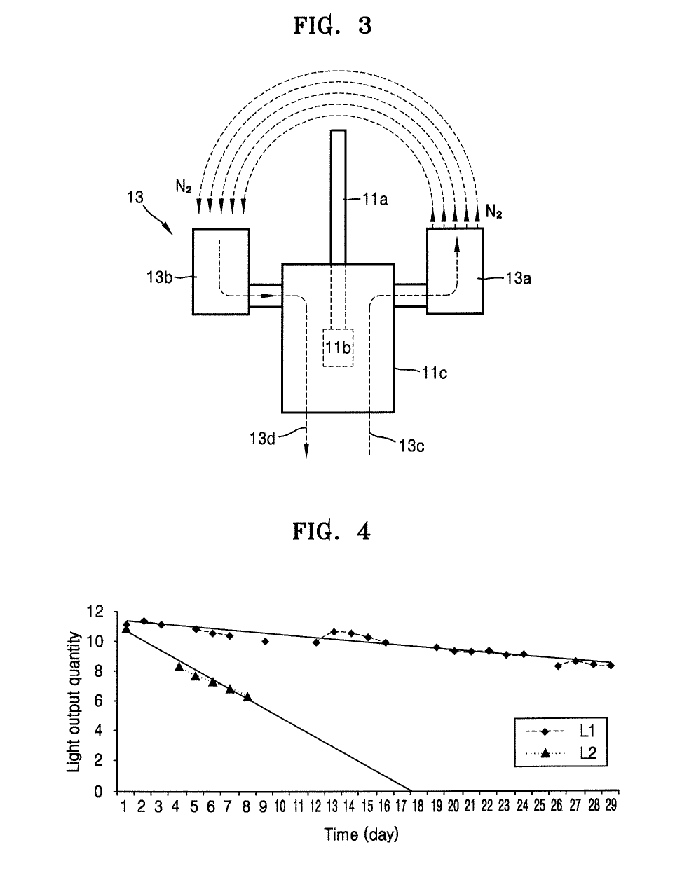

FIG. 3 is a diagram depicting an air circulation formed by a blowing unit of the thin-film thickness measurement apparatus of FIG. 2. Referring to FIG. 3, the air circulation of a clean nitrogen gas supplied from the blowing unit 13 may be formed around the front end of the optical fiber 11a. The clean nitrogen gas may be introduced from outside the deposition chamber 40 through the inflow line 13c and may be ejected towards the front end of the optical fiber 11a through the ejecting block 13a. The ejected nitrogen gas may be sucked through the sucking block 13b, and then discharged through the discharge line 13d. Thus, the clean nitrogen gas may circulate around the front end of the optical fiber 11a.

The inside of the deposition chamber 40 in which the deposition process is performed may have a nitrogen gas atmosphere. As the deposition process is performed, the nitrogen gas atmosphere may change to a contaminated gas state in which the source of the thin-film is mixed into the atmosphere in the deposition chamber 40. When the clean nitrogen gas circulates around the front end of the optical fiber 11a, the front end coming into contact with a contaminated gas inside the deposition chamber 40 may be reduced or eliminated. Thus, the front end may continuously maintain a clean state even when a separate cleaning operation is not performed.

FIG. 4 is a graph showing a light quantity decreasing state of the thin-film thickness measurement apparatus of FIG. 2 according to time, together with a comparative example. Referring to FIG. 4, the graph shows a decreasing degree of a light output quantity when the blowing unit 13 is activated, together with a comparative example L2. In the comparative example L2 in which a deposition operation is performed without the blowing unit 13, a light quantity may decrease relatively rapidly according to time. In an example L1 according to an exemplary embodiment of the present invention in which the blowing unit 13 is activated, a light quantity may decrease relatively slowly.

The front end of the optical fiber 11a in the comparative example L2 may be cleaned once in two weeks, and the front end of the optical fiber 11a in the example L1 may be be cleaned once in four months to maintain measurement accuracy.

The thin-film deposition apparatus 100 may include the thin-film thickness measurement apparatus 10 according to an exemplary embodiment of the present invention. A method of using the thin-film deposition apparatus will be described in more detail below.

The substrate 20 may be disposed inside the deposition chamber 40 including the deposition source suppler 30 and the thin-film thickness measurement apparatus 10.

When the source of the thin-film is supplied from the deposition source supplier 30, the thin-film may be formed on the substrate 20, and the thin-film thickness measurement apparatus 10 may measure the thickness of the thin-film in substantially real-time. The thin-film thickness measurement apparatus 10 may provide the thickness measurement back to the thin-film deposition apparatus 100.

The blowing unit 13 may be activated in the thin-film thickness measurement apparatus 10 to circulate clean nitrogen at the front end of the optical fiber 11a. Thus, the thickness of the thin-film may be accurately measured even if the deposition process is performed for a relatively long period of time.

The thin-film deposition apparatus 100 may be used, for example, to form a pattern of an organic film or a counter electrode of an organic light-emitting display apparatus.

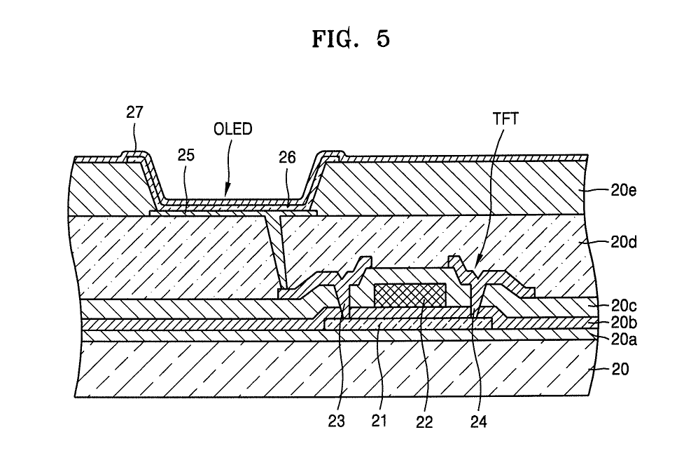

FIG. 5 is a cross-sectional view of an organic light-emitting display apparatus as an example of a target for performing deposition by using the thin-film deposition apparatus of FIG. 1. The substrate illustrated in FIG. 5 may be substantially the same as the substrate 20 of the organic light-emitting display apparatus illustrated in FIG. 1.

Referring to FIG. 5, a buffer layer 20a may be disposed on the substrate 20, and a thin-film transistor TFT may be disposed on the buffer layer 20a.

The thin-film transistor TFT may include a semiconductor active layer 21, a gate insulating film 20b covering the semiconductor active layer 21, and a gate electrode 22 disposed on the gate insulating film 20b.

An interlayer insulating film 20c may cover the gate electrode 22, and a source electrode 24 and a drain electrode 23 may be disposed on the interlayer insulating film 20c.

The source electrode 24 and the drain electrode 23 may respectively contact a source region and a drain region of the semiconductor active layer 21 through contact holes formed in the gate insulating film 20b and the interlayer insulating film 20c.

A pixel electrode 25 of an organic light-emitting device OLED may be connected to the drain electrode 23. The pixel electrode 25 may be disposed on a planarization film 20d, and a pixel-defining layer 20e may cover the pixel electrode 25. An opening may be formed in the pixel-defining layer 20e. An organic film 26 of the organic light-emitting device OLED may be disposed in the opening. A counter electrode 27 may be disposed on the organic film 26.

When the thin-film deposition apparatus 100 according to an exemplary embodiment of the present invention is used to form the organic film 26 or the counter electrode 27, a thin film having a precise thickness may be formed as described above, and a maintenance time for cleaning may be reduced, thus increasing productivity.

Thus, by using the thin-film thickness measurement apparatus 10 and the thin-film deposition apparatus 100, the light emitter of the thin-film thickness measurement apparatus 10 including the clean nitrogen gas circulation may be maintained in a relatively clean state. Thus, measurement accuracy of a thickness of a deposited thin-film may increase, and a separate maintenance time for cleaning the light emitter of the thin-film thickness measurement apparatus 10 may be reduced or eliminated, thus increasing productivity of a deposition process.

The ejecting block 13a and the sucking block 13b of the blowing unit 13 may include an acetal material. Thus, the blowing unit 13 may have a relatively strong structure and an undesired leakage of gas may be reduced or eliminated.

While the present invention has been shown and described with reference to the exemplary embodiments thereof, it will be apparent to those of ordinary skill in the art that various changes in form and detail may be made thereto without departing from the spirit and scope of the present invention.

What is claimed is:

1. A thin-film thickness measurement apparatus comprising:
a light output unit including a light emitter configured to emit light onto a target;
a light receiving unit configured to receive light reflected from the target; and
a blowing unit configured to eject a gas around the light emitter.

2. The thin-film thickness measurement apparatus of claim 1, wherein the light output unit comprises:
a housing including a light source; and
an optical fiber projecting from the housing to radiate light from the light source towards the target.

3. The thin-film thickness measurement apparatus of claim 2, wherein the blowing unit comprises:
an ejecting block ejecting a gas towards a front end of the optical fiber facing the target; and
a sucking block collecting the gas ejected from the ejecting block.

4. The thin-film thickness measurement apparatus of claim 3, wherein the blowing unit is configured to create air circulation including the gas from the ejecting block to the sucking block around the front end of the optical fiber.

5. The thin-film thickness measurement apparatus of claim 3, wherein the ejecting block and the sucking block are coupled to the housing, and wherein an inflow line connected to the ejecting block and a discharge line connected to the sucking block are disposed in the housing.

6. The thin-film thickness measurement apparatus of claim 3, wherein the ejecting block and the sucking block comprise an acetal material.

7. The thin-film thickness measurement apparatus of claim 1, wherein the gas comprises nitrogen.

8. A thin-film deposition apparatus comprising:
a deposition chamber configured to house a target;
a deposition source supplier configured to supply a source of a thin-film to be deposited on the target; and
a thin-film thickness measurement apparatus configured to measure a thickness of the thin-film deposited on the target,
wherein the thin-film thickness measurement apparatus comprises:
a light output unit including a light emitter configured to emit light onto the target;
a light receiving unit configured to receive light reflected from the target; and
a blowing unit configured to eject a gas around the light emitter.

9. The thin-film deposition apparatus of claim 8, wherein the light output unit comprises:
a housing including a light source; and
an optical fiber projecting from the housing to radiate light from the light source towards the target.

10. The thin-film deposition apparatus of claim 9, wherein the blowing unit comprises:
an ejecting block ejecting a gas towards a front end of the optical fiber facing the target; and
a sucking block collecting the gas ejected from the ejecting block.

11. The thin-film deposition apparatus of claim 10, wherein the blowing unit is configured to create air circulation including the gas from the ejecting block to the sucking block around the front end of the optical fiber.

12. The thin-film deposition apparatus of claim 10, wherein the ejecting block and the sucking block are coupled to the housing, and wherein an inflow line connected to the ejecting block and a discharge line connected to the sucking block are disposed in the housing.

13. The thin-film deposition apparatus of claim 10, wherein the ejecting block and the sucking block comprise an acetal material.

14. The thin-film deposition apparatus of claim 8, wherein the gas comprises nitrogen.
